(19) United States
(12) Patent Application Publication
(10) Pub. No.: US 2015/0107771 A1
(43) Pub. Date: Apr. 23, 2015

(54) TRAP APPARATUS AND SUBSTRATE PROCESSING APPARATUS

(71) Applicants: TOKYO ELECTRON LIMITED, Tokyo (JP); TOHOKU SEIMITSU CO., LTD., Iwate (JP)

(72) Inventors: Atsushi KOBAYASHI, Miyagi (JP); Shinji AKIYAMA, Miyagi (JP); Shuuichi ANDOU, Iwate (JP); Katsuhiro KOSUGA, Iwate (JP); Takahiro YAMAMOTO, Iwate (JP)

(73) Assignees: TOHOKU SEIMITSU CO., LTD., Iwate (JP); TOKYO ELECTRON LIMITED, Tokyo (JP)

(21) Appl. No.: 14/518,079

(22) Filed: Oct. 20, 2014

(30) Foreign Application Priority Data
Oct. 21, 2013 (JP) 2013-218718

(51) Int. Cl. H01J 37/32; B01D 46/00; C23C 16/44

(52) U.S. Cl. CPC H01J 37/32871; C23C 16/4412; B01D 46/0023
USPC 156/345.29; 118/723 R; 55/488; 55/485

(57) ABSTRACT

A trap apparatus includes: a first cylindrical member including a space; a second cylindrical member removably disposed in the space and including side opening which allows a gas stream to flow in therethrough, and a downstream side opening which allows the gas stream flowing in from the upstream side opening to flow out therethrough; a downstream side trap member which is disposed inside the second cylindrical member to block the downstream side opening; and an upstream side trap member which is disposed between the downstream side trap member and the upstream side opening of the second cylindrical member and includes a concave portion recessed in a direction approaching the downstream side trap member.

### CROSS-REFERENCE TO RELATED APPLICATIONS

This application is based on and claims priority from Japanese Patent Application No. 2013-218718 filed on Oct. 21, 2013 with the Japan Patent Office, the disclosure of which is incorporated herein in its entirety by reference.

### TECHNICAL FIELD

Various aspects and exemplary embodiments of the present disclosure relate to a trap apparatus and a substrate processing apparatus.

### BACKGROUND

In a semiconductor manufacturing process, a substrate processing apparatus that performs a plasma processing for the purpose of, for example, depositing or etching a thin film, has been widely used. As a substrate processing apparatus, a plasma processing apparatus such as, for example, a plasma chemical vapor deposition (CVD) apparatus which performs a deposition processing of a thin film or a plasma etching apparatus which performs an etching processing, may be exemplified.

The substrate processing apparatus includes, for example, a processing container configured to perform plasma processing on a substrate to be processed, an exhaust unit configured to reduce a pressure within the processing container, and an exhaust flow path that connects the processing container and the exhaust unit.

However, in the substrate processing apparatus, since a reaction product that is produced by a plasma reaction in the processing container is included in the gas stream flowing through the exhaust flow path, it is required to remove a reaction product in a gas stream. From this point, Japanese Patent No. 4944331 discloses a structure in which an inner cylindrical member is provided in an outer cylindrical member connected to the exhaust flow path and, a mesh type trap medium is disposed to block a downstream side opening of the inner cylindrical member so as to trap the reaction product in the gas stream by using the trap medium.

### SUMMARY

A trap apparatus according to an aspect of the present disclosure includes: a first cylindrical member including a space; a second cylindrical member removably disposed in the space and including an upstream side opening which allows a gas stream to flow in therethrough, and a downstream side opening which allows the gas stream flowing in from the upstream side opening to flow out therethrough; a downstream side trap member which is disposed inside the second cylindrical member to block the downstream side opening; and an upstream side trap member which is disposed between the downstream side trap member and the upstream side opening of the second cylindrical member and includes a concave portion recessed in a direction toward the downstream side trap member.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view schematically illustrating a configuration of a plasma processing apparatus according to an exemplary embodiment.

FIG. 2 is a cross-sectional view illustrating a detailed configuration of a trap apparatus of an exemplary embodiment.

FIG. 3 is a perspective view illustrating an external appearance of an upstream side trap member when viewed from an upstream side opening of an inner cylindrical member of an exemplary embodiment.

FIG. 4 is a perspective view illustrating an external appearance of an upstream side trap member when viewed from a downstream side trap member of an exemplary embodiment.

FIG. 5 is a cross-sectional view illustrating Modified Example 1 of the trap apparatus of the exemplary embodiment.

FIG. 6 is a cross-sectional view of Modified Example 2 of the trap apparatus of the exemplary embodiment.

### DETAILED DESCRIPTION

In the following detailed description, reference is made to the accompanying drawings, which form a part hereof The exemplary embodiments described in the detailed description, drawing, and claims are not meant to be limiting. Other exemplary embodiments may be utilized, and other changes may be made, without departing from the spirit or scope of the subject matter presented here.

It is difficult to effectively remove a reaction product included in a gas stream by disposing only a mesh type trap medium to block a downstream side opening of an inner cylindrical member which is similar to conventional structure.

A trap apparatus according to an aspect of the present disclosure includes: a first cylindrical member including a space; a second cylindrical member removably disposed in the space and including an upstream side opening which allows a gas stream to flow in therethrough, and a downstream side opening which allows the gas stream flowing in from the upstream side opening to flow out therethrough; a downstream side trap member which is disposed inside the second cylindrical member to block the downstream side opening; and an upstream side trap member which is disposed between the downstream side trap member and the upstream side opening of the second cylindrical member and includes a concave portion recessed in a direction toward the downstream side trap member.

In the above-described trap apparatus, the upstream side trap member is formed in a shape in which a diameter of the concave portion gets smaller along the direction approaching the downstream side trap member.

In the above-described trap apparatus, the upstream side trap member is formed in a conical shape which gets sharper in the direction approaching the downstream side trap member.

In the above-described trap apparatus, a plurality of upstream side trap members is disposed between the downstream side trap member and the upstream side opening of the second cylindrical member along the direction toward the downstream side trap member.

In the above-described trap apparatus, each of the plurality of upstream side trap members include through holes which allow the gas stream to pass therethrough and densities and/or diameters of the through holes is different among the pluralities of upstream side trap members.

In the above-described trap apparatus, the first cylindrical member includes: a cylinder body which surrounds a lateral side of the second cylindrical member; an upstream side end wall of the cylinder body which is removably mounted on the cylinder body to block an upstream side opening side end of the second cylindrical member; and a downstream side end wall of the cylinder body which is removably mounted on the cylinder body to block a downstream side opening side end of the second cylindrical member to form the space together with the cylinder body and the upstream side end wall. The downstream side trap member is disposed at a position spaced apart from the downstream side end wall by a predetermined distance toward the upstream side end wall inside the second cylindrical member.

A substrate processing apparatus according to another aspect of the present disclosure includes: a processing container configured to perform a plasma processing on a substrate to be processed; an exhaust device configured to reduce a pressure within the processing container; an exhaust flow path which connects the processing container and the exhaust device; and a trap apparatus provided in the exhaust flow path. The trap apparatus includes: a first cylindrical member including a space, a second cylindrical member removably disposed in the space and including an upstream side opening which allows a gas stream to flow in therethrough, and a downstream side opening which allows the gas stream flowing in from the upstream side opening to flow out therethrough; a downstream side trap member which is disposed inside the second cylindrical member to block the downstream side opening; and an upstream side trap member which is disposed between the downstream side trap member and the upstream side opening of the second cylindrical member and includes a concave portion recessed in a direction approaching the downstream side trap member.

According to various aspects and exemplary embodiments of the present disclosure, a trap apparatus and a substrate processing apparatus which are capable of effectively removing a reaction product included in gas stream is realized.

Hereinafter, a disclosed trap apparatus and a substrate processing apparatus disclosed herein will be described in detail with reference to accompanying drawings. Meanwhile, the same or corresponding elements in respective drawings will be denoted by the same reference numerals. Hereinafter, descriptions will be made on an example in which a substrate processing apparatus disclosed herein is applied to, for example, a plasma chemical vapor deposition (CVD) apparatus which performs a deposition processing of a thin film or a plasma etching apparatus which performs an etching processing.

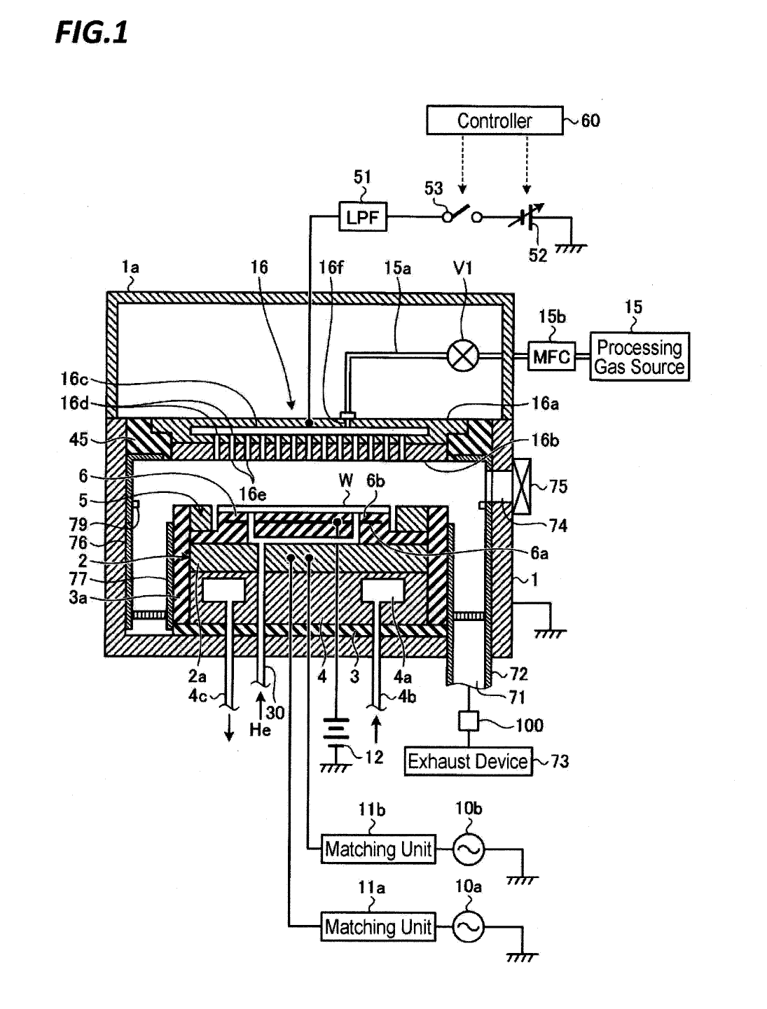

First, a whole configuration of a plasma processing apparatus will be described. FIG. 1 is a vertical cross-sectional view schematically illustrating a configuration of a plasma processing apparatus according to an exemplary embodiment.

The plasma processing apparatus includes a processing chamber (a processing container) 1 which is hermetically configured and is at an electrical ground potential. The processing chamber 1 has a cylindrical shape and is made of, for example, aluminum. The processing chamber 1 defines a plasma processing space for performing a plasma processing. In the processing chamber 1, a lower electrode 2 is provided on which a semiconductor wafer W as a substrate to be processed is mounted. A base material 2a of the lower electrode 2 is made of a conductive metal, for example, aluminum. The lower electrode 2 is supported by a conductive support table 4 through an insulating plate 3. A cylindrical inner wall member 3a made of, for example, quartz is provided to surround the lower electrode 2 and the support table 4.

A first RF power source 10a is connected to the base material 2a of the lower electrode 2 through a first matching unit 11a, and a second RF power source 10b is connected to the base material 2a through a second matching unit 11b. The first RF power source 10a is used for generating plasma. From the first RF power source 10a, a high frequency power at a predetermined frequency (27 MHz or higher, for example, 40 MHz) is supplied to the base material 2a of the lower electrode 2. Further, the second RF power source 10b is used for drawing-in ions (for bias). From the second RF power source 10b, a high frequency power at a predetermined frequency lower than that from the first RF power source 10a is supplied to the base material 2a of the lower electrode 2.

An upper electrode 16 is provided above the lower electrode 2 so as to face the lower electrode 2 through the plasma processing space of the processing chamber 1. The upper electrode 16 and the lower electrode 2 are configured to function as a pair of electrodes. A space between the upper electrode 16 and the lower electrode 2 becomes the plasma processing space for generating plasma.

A coolant passage 4a is formed inside the support plate 4, and a coolant inlet pipe 4b and a coolant outlet pipe 4c are connected to the coolant passage 4a. When an appropriate coolant, for example, cooling water is circulated in the coolant passage 4a, the support plate 4 and the lower electrode 2 may be controlled to a predetermined temperature. Further, a backside gas supply pipe 30 is provided through, for example, the lower electrode 2 so as to supply a cold heat transferring gas (a backside gas) to a rear surface side of the semiconductor wafer W. The backside gas supply pipe 30 is connected to a backside gas supply source not illustrated. With such a configuration, a temperature of the semiconductor wafer W placed on top surface of the lower electrode 2 may be controlled to a predetermined temperature.

The upper electrode 16 is placed on a ceiling wall portion of the processing chamber 1. The upper electrode 16 includes a body 16a, and a ceiling plate 16b which forms an electrode plate, and is supported on an upper portion of the processing chamber 1 by an insulative member 45. The body 16a is made of a conductive material such as aluminum having an anodized surface and configured to removably support the ceiling plate 16b on the bottom thereof.

A gas diffusion chamber 16c is provided inside the body 16a, and a plurality of gas passage holes 16d is formed in a bottom portion of the body 16a to be positioned below the gas diffusion chamber 16c. Also, in the ceiling plate 16b, gas introduction holes 16e are formed to penetrate the ceiling plate 16b in a thickness direction and to overlap with the gas passage holes 16d. With this configuration, the processing gas supplied to the gas diffusion chamber 16c is dispersed in a shower form and supplied to into the processing chamber 1 through the gas passage holes 16d and the gas introduction holes 16e. Meanwhile, since a pipe (not illustrated) is provided, for example, in the body 16a to circulate the coolant, the upper electrode 16 may be cooled to a desired temperature during the plasma etching process.

A gas introduction port 16f is formed in the body 16a so as to introduce the processing gas to the gas diffusion chamber 16c. A gas supply pipe 15a is joined to the gas inlet 16f, and the other end of the gas supply pipe 15a is joined to the gas supply source 15 which supplies a processing gas for etching. A mass flow controller (MFC) 15b and a switching valve V1 are provided in the gas supply pipe 15a in this order. The processing gas for plasma etching is supplied from the processing gas source 15 to the gas diffusion chamber 16c through the gas supply pipe 15a, and from the gas diffusion chamber 16c, the processing gas is dispersed in a shower form and supplied into the processing chamber 1 through the gas passage holes 16d and the gas introduction holes 16e.

A variable direct current (DC) power supply 52 is electrically connected to the upper electrode 16 through a low pass filter (LPF) 51. The variable DC power supply 52 may be turned ON/Off through an ON/OFF switch 53 to supply power. A current and voltage of the variable DC power supply 52 and the ON/OFF of the ON/OFF switch 53 are controlled by a controller 60 to be described later. Meanwhile, when high frequency waves are supplied to the lower electrode 2 from the first RF power source 10a and the second RF power source 10b as described later and thus plasma is generated in the plasma processing space, the ON/OFF switch 53 is turned ON by the controller 60 as needed, thereby applying a predetermined DC voltage to the upper electrode 16.

A cylindrical ground conductor 1a is provided to extend higher than the height of the upper electrode 16 from the side wall of the processing chamber 1. The cylindrical ground conductor 1a has a ceiling wall on the top thereof.

An exhaust port 71 is formed in the bottom portion of the processing chamber 1, and an exhaust pipe 72 and an exhaust device 73 are connected to the exhaust port 71. The exhaust pipe 72 is an exhaust flow path that connects the processing chamber 1 and the exhaust device 73. The exhaust device 73 includes a vacuum pump. When the vacuum pump is operated, the inside of the processing chamber 1 may be decompressed to a predetermined degree of vacuum. A product produced by a plasma reaction in the processing chamber 1 (hereinafter, referred to as a “reaction product”) flows through the exhaust pipe 72 together with a gas stream as the inside of the processing chamber 1 is decompressed by the exhaust device 73.

In the exhaust pipe 72, a trap apparatus 100 is provided to remove the reaction product from the gas stream that flows through the exhaust pipe 72. Hereinafter, the detailed configuration of the trap apparatus 100 will be described.

Meanwhile, a carry-in/carry-out port 74 of a wafer W is formed in the side wall of the processing chamber 1 and a gate valve 75 is provided in the carry-in/carry-out port 74 to open/close the carry-in/carry-out port 74.

Reference numerals 76 and 77 in the figure indicate detachable vapor deposition shields. The deposition shield 76 is formed along an inner wall of the processing chamber 1, and serves to prevent etching byproduct (deposit) from being adhered to the processing chamber 1. A conductive member (a GND block) 79 serially connected to a ground is provided on the vapor deposition shield 76 at a height which is substantially the same as the height of the semiconductor wafer W. As a result abnormal discharge is prevented.

The operation of the plasma processing apparatus described above is generally controlled by the controller 60. The controller 60 includes a process controller provided with a CPU to control each element of the plasma processing apparatus, a user interface, and a storage unit.

The user interface of the controller 60 includes, for example, a keyboard through which a process manager performs an input operation of a command so as to manage the plasma etching apparatus, and a display that visualizes and displays an operating circumstance of the plasma etching apparatus.

The storage unit of the controller 60 stores a control program (software) to implement various processings executed in the plasma etching apparatus by a control of the process controller, or a recipe in which, for example, processing condition data are stored. When an arbitrary recipe is read out by, for example, an instruction from the user interfaces of the controller 60 to be executed by the process controller as needed, a desired processing may be performed by the plasma etching apparatus under the control of the process controller of the controller 60. Further, as for the recipe such as, for example, the control program or the processing condition data a recipe stored in the computer-readable storage medium (e.g., a hard disk, a CD, a flexible disk, or a semiconductor memory) may be used or a recipe transmitted from any other device through, for example, a dedicated network line at any time may be used online.

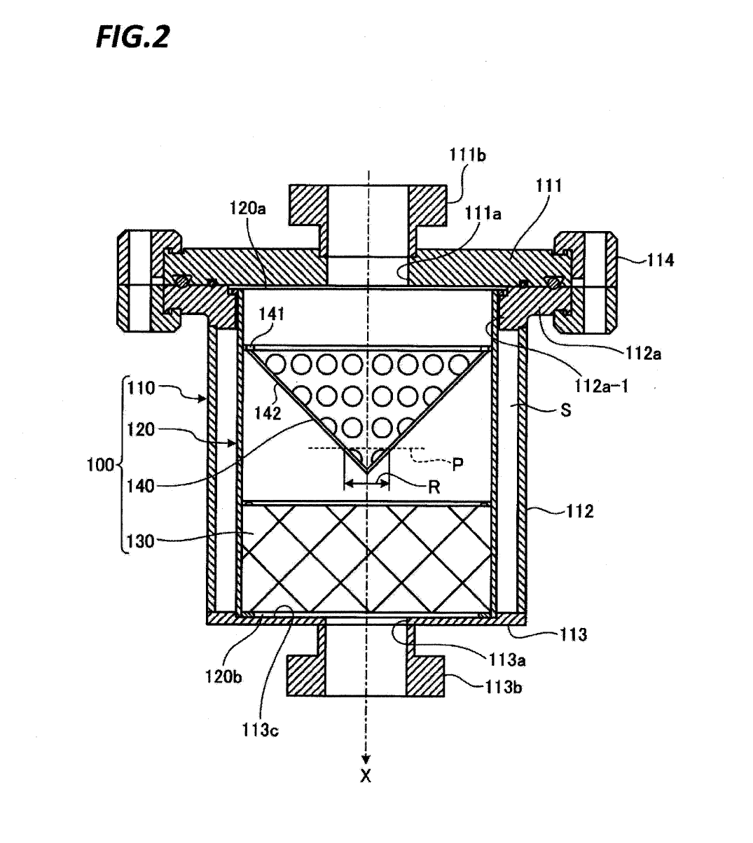

Next, a detailed configuration of the trap apparatus 100 equipped in the exhaust pipe 72 will be described. FIG. 2 is a cross-sectional view illustrating the detailed configuration of the trap apparatus of an exemplary embodiment. In the description of FIG. 2, the exhaust pipe 72 positioned nearer to an exhaust port 71 side of the processing chamber 1 than the trap apparatus 100 will be referred to as an upstream side exhaust pipe 72, and an exhaust pipe 72 which is positioned nearer to the exhaust device 73 than the trap apparatus 100 will be referred to as a downstream side exhaust pipe 72.

As illustrated in the FIG. 2, the trap apparatus 100 includes an outer cylindrical member 110 which has an internal space S and an inner cylindrical member 120 removably disposed in the internal space of the outer cylindrical member 110. The trap apparatus 100 further includes a downstream side trap member 130 and an upstream side trap member 140 which are disposed inside the inner cylindrical member 120.

The outer cylindrical member 110 includes an upstream side end wall 111, a cylinder body 112, and a downstream side end wall 113. The space surrounded by the upstream side end wall 111, the cylinder body 112, and the downstream side end wall 113 forms the internal space S of the outer cylindrical member 110.

The upstream side end wall 111 is removably mounted on the cylinder body 112 so as to block an end of the cylinder body 112 at an upstream side opening 120a side of the inner cylindrical member 120. Specifically, the upstream side end wall 111 is removably mounted on a flange portion 112a of the cylinder body 112 through a clamp 114. An opening 111a is formed at the center of the upstream side end wall 111, and a base end of an upstream side joint 111b is connected to the opening 111a. A distal end of the upper joint 111b is connected to the exhaust pipe 72 which is positioned nearer to the exhaust port 71 side than the trap apparatus 100 i.e., the upstream side exhaust pipe 72. The gas stream passing through the upstream side exhaust pipe 72 is introduced into the upstream side opening 120a of the inner cylindrical member 120 to be described hereinafter, through the opening 111a and the upstream side joint 111b of the upstream side end wall 111.

The cylinder body 112 is a cylindrical member that surrounds the lateral side of the inner cylindrical member 120. The flange portion 112a is formed on one end of the cylinder body 112. An inner wall 112a-1 of the flange portion 112a protrudes in a direction approaching the outer circumferential surface of the inner cylindrical member 120 so as to support the outer circumferential surface of the inner cylindrical member 120.

The downstream side end wall 113 is removably mounted on an end of the cylinder body 112 opposite to the flange portion 112a, i.e. to block the end of the cylinder body 112 at the downstream side opening 120b side of the inner cylindrical member 120. An opening 113a is formed at the center of the downstream side end wall 113, and a base end of a downstream side joint 113b is joined to the opening 113a. A distal end of the downstream side joint 113b is joined to the exhaust pipe 72 which is positioned nearer to the exhaust apparatus device 73 than the trap apparatus 100, i.e. the downstream side exhaust pipe 72. The gas stream flowing out from the downstream side opening 120b of the inner cylindrical member 120 to be described hereinafter is introduced to the downstream side exhaust pipe 72 through the opening 113a of the downstream side end wall 113 and the downstream side joint 113b. Also, on the surface of the downstream side end wall 113 at the upstream side end wall 111 side, the downstream side opening 120b side end of the inner cylindrical member 120, i.e., an accommodation concave portion 113c is formed to accommodate bottom portion of the inner cylindrical member 120.

When the bottom portion of the inner cylindrical member 120 is accommodated in the accommodation concave portion and the outer circumferential surface of the inner cylindrical member 120 is supported by the flange portion 112a of the cylinder body 112 so that the upper portion of the inner cylindrical member 120 is blocked by the upstream side end wall 111, the inner cylindrical member 120 is mounted in the internal space S of the outer cylindrical member 110. Meanwhile, when the upper portion of the inner cylindrical member 120 is released from the upstream side end wall 111 and the bottom portion of the inner cylindrical member 120 is released from the accommodation concave portion 113c of the downstream side end wall 113, the inner cylindrical member 120 may be removed from the internal space S of the outer cylindrical member 110.

The inner cylindrical member 120 includes the upstream side opening 120a and the downstream side opening 120b. The upstream side opening 120a allows the gas stream introduced from the upstream side exhaust pipe 72 through the upstream side joint 111b and the opening 111a to flow in therethrough. The downstream side opening 120b allows the gas stream flowing in from the upstream side opening 120a to flow out to the downstream side exhaust pipe 72 therethrough.

The downstream side trap member 130 is disposed inside the inner cylindrical member 120 to block the downstream side opening 120b. Specifically, the downstream side trap member 130 is disposed at a position which is not spaced apart from the downstream side end wall 113 towards the upstream side end wall 111 in the inner cylindrical member 120. The downstream side trap member 130 is formed of a material that is pervious to the gas stream flowing in from the upstream side opening 120a and has a function of trapping the reaction product included in the gas stream. For example, the downstream side trap member 130 is formed of a mesh type material including, for example, a metallic mesh.

The upstream side trap member 140 is disposed between the downstream side trap member 130 and the upstream side opening 120a of the inner cylindrical member 120. The upstream side trap member 140 is formed of a material that is pervious to the gas stream flowing in from the upstream side opening 120a and has a function of trapping the reaction product included in the gas stream. For example, the upstream side trap member 130 is formed of a material which includes through holes through which the gas stream passes such as a punching metal.

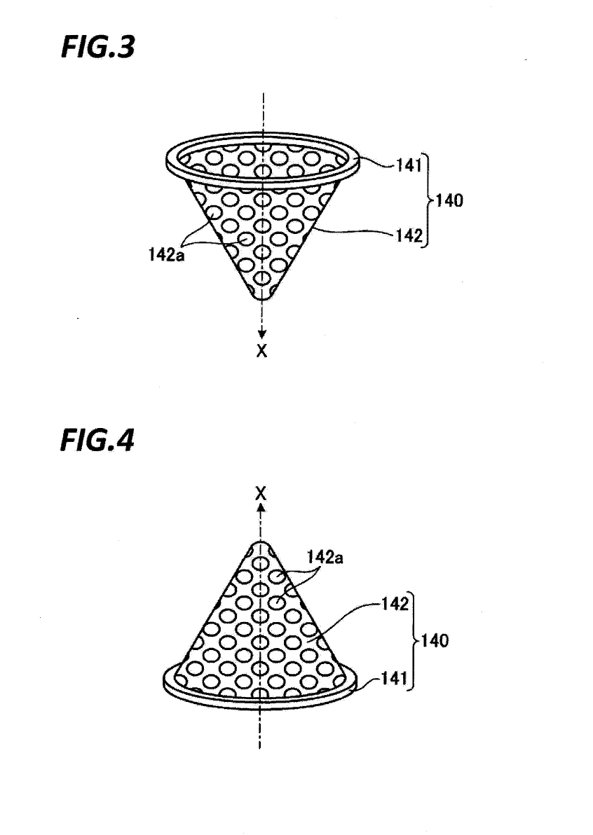

FIG. 3 is a perspective view illustrating an external appearance of the upstream side trap member when viewed from the upstream side opening side of the inner cylindrical member of the exemplary embodiment. FIG. 4 is a perspective view illustrating an external appearance of the upstream side trap member when viewed from the downstream side trap member of the exemplary embodiment.

As illustrated in FIGS. 2-4, the upstream side trap member 140 includes an annular base portion 141 and a concave portion 142 joined thereto. The annular base portion 141 is attached to the inner surface of the inner cylindrical member 120 by, for example, welding.

The concave portion 142 is recessed in a direction approaching the downstream side trap member 130. In other word, the concave portion 142 is recessed along the flowing direction of the gas stream which flows in from the upstream side opening 120a of the inner cylindrical member 120 toward the downstream side trap member 130. A plurality of through holes 142a is formed in the concave portion 142 so as to pass the gas stream therethrough. A density and a diameter of the through holes 142a are set so that the upstream side trap member 140 is pervious to the gas stream flowing in from the upstream side opening 120a and exhibits a function of trapping the reaction product included in the gas stream.

Also, the upstream side trap member 140 is formed in a shape in which the radius R of the concave portion 142 gets smaller along the direction approaching the downstream side trap member 130. Here, the diameter R of the concave portion 142 refers to a width between facing edges among edges of the cross-section of the concave portion 142 projecting on a virtual plane P orthogonal to an axis X which is virtually set as extending in the direction approaching the downstream side trap member 130. In an exemplary embodiment, as illustrated in FIGS. 2-4, the upstream side trap member 140 is formed in a conical shape which gets sharper in the direction approaching the downstream side trap member 130, i.e. in the direction where the axis X extends.

Subsequently, an example of an action obtained by the trap apparatus 100 provided in the exhaust pipe will be described. The reaction product produced by the plasma reaction in the processing chamber 1 passes through the exhaust pipe 72 together with the gas stream because the inside of the processing chamber 1 is decompressed by the exhaust device 73.

Subsequently, the gas stream that passes through the exhaust pipe 72 which is positioned nearer to the exhaust port 71 side of the processing chamber 1 than the trap apparatus 100 is introduced into the upstream side opening 120a of the inner cylindrical member 120 through the upstream side joint 111b of the upstream side end wall 111 and the opening 111a. The upstream side trap member 140 is pervious to the gas stream flowing in from the upstream side opening 120a, and traps the reaction product included in the gas stream. Specifically, the upstream side trap member 140 is pervious to the gas stream through the plurality of through holes 142a of the concave portion 142, and traps the reaction products included in the gas stream at a portion other than the plurality of through holes 142a of the concave portion 142. Here, the concave portion 142 is recessed in the direction approaching the downstream side trap member 130. Accordingly, since the force acting on the gas stream from the upstream side trap member in a direction reverse to the direction toward the downstream side trap member 130 is suppressed, a back flow of the gas stream towards the upstream side opening 120a in the upstream side trap member 140 may be avoided.

Subsequently, the gas stream that has passed the upstream side trap member 140 reaches the downstream side trap member 130. The downstream side trap member 130 is pervious to the gas stream that has passed the upstream side trap member 140 and traps the reaction product included in the gas stream but not trapped by the upstream side trap member 140.

Subsequently, the gas stream that has passed through the upstream side trap member 140 and the downstream side trap member 130 flows out to the exhaust pipe 72 which is positioned nearer to the exhaust device 73 side than the trap apparatus 100 via the downstream side opening 120b of the inner cylindrical member 120.

As described above, according to an exemplary embodiment of the trap apparatus, the downstream side trap member 130 is disposed inside the inner cylindrical member 120 and the upstream side trap member 140 including the concaved portion 142 recessed in the direction approaching the downstream side trap member 130 is disposed between the downstream side trap member 130 and the upstream side opening 120a of the inner cylindrical member 120. According to the exemplary embodiment of the trap apparatus, the reaction product included in the gas stream may be trapped by using two trap members, and the force acting on the gas stream from the upstream side trap member 140 in a direction reverse to the direction toward the downstream side trap member 130 may be suppressed. As a result, according to the trap apparatus of the exemplary embodiment, the reaction product included in the gas stream may be effectively removed.

Also, in an exemplary embodiment of the trap apparatus, the upstream side trap member 140 is formed in a shape in which the diameter R of the concave portion 142 gets smaller along the direction toward the downstream side trap member 130. Due to this, a reaction product trapping ability by the concave portion 142 may be improved the trap apparatus according the exemplary embodiment. Therefore, according to the trap apparatus of the exemplary embodiment, the reaction product included in the gas stream may be removed more effectively.

Furthermore, in an exemplary embodiment of the trap apparatus, the upstream side trap member 140 is formed in a conical shape which gets sharper in the direction approaching the downstream side trap member 130. Here, when the upstream side trap member 140 is formed using, for example, a punching metal, the conical shape is one of the shapes that can be easily shaped using a metal. For this reason, according to the exemplary embodiment of the trap apparatus, the reaction product trapping ability may be improved while enhancing formability of the upstream side trap member 140, the ability of the concave portion 142 in trapping the reaction product may be improved. As a result, according to the exemplary embodiment of the trap apparatus, the reaction product included in the gas stream may be effectively removed while reducing a burden associated with manufacturing the apparatus.

### Modified Example 1

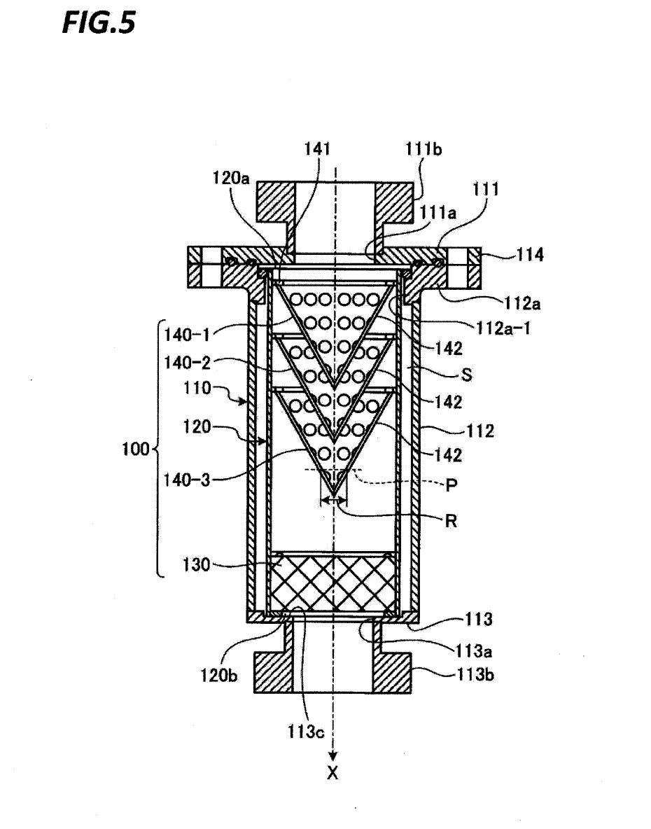

In the exemplary embodiment described above, although the trap apparatus 100 in which a single upstream side trap member 140 is disposed between the downstream side trap member 130 and the upstream side opening 120a of the inner cylindrical member 120 has been illustrated as an example, the present disclosure is not limited thereto. Below, a trap apparatus related to Modified Example 1 will be described. FIG. 5 is a sectional view of Modified Example 1 of the trap apparatus of an exemplary embodiment.

As illustrated in FIG. 5, in the trap apparatus 100 according to Modified Example 1, a plurality of upstream side trap members 140 is disposed between the downstream side trap member 130 and the upstream side opening 120a of the inner cylindrical member 120 along the direction toward the downstream side trap member 130. In Modified Example 1, three upstream side trap members 140 are disposed along the direction toward the downstream side member 130, i.e. in the direction where the axis X extends. In FIG. 5, the three upstream side trap members 140 are illustrated as an upstream side trap member 140-1, an upstream side trap member 140-2, and an upstream side trap member 140-3 from the upstream side opening 120a of the inner cylindrical member 120 along the direction where the axis X extends. The plurality of through holes 142a is formed in a concave portion 142 of each of the upstream side trap member 140-1, the upstream side trap member 140-2, and the upstream side trap member 140-3. In Modified Example 1, the densities and the diameters of the through holes 142a are the same among the upstream side trap member 140-1, the upstream side trap member 140-2, and the upstream side trap member 140-3.

According to Modified Example 1 of the trap apparatus, the downstream side trap member 130 is disposed inside the inner cylindrical member 120 and the plurality of upstream side trap members 140 is disposed between the downstream side trap member 130 and the upstream side opening 120a of the inner cylindrical member 120 along the direction toward the downstream side trap member 130. Due to this, according to the Modified Example 1 of the trap apparatus, the reaction product included in the gas stream may be trapped by using quadruple trap members while the force acting on the gas stream from the upstream side trap member 140 in a direction reverse to the direction toward the downstream side trap member 130 may be suppressed. As a result, the reaction product included in the gas stream may be removed more effectively according to Modified Example 1 of the trap apparatus.

Meanwhile, in Modified Example 1, although an example in which the densities and the diameters of the exemplary through holes 142a are the same with each other among the upstream side trap member 140-1, the upstream side trap member 140-2, and the upstream side trap member 140-3, the present disclosure is not limited thereto. For example, the densities or the diameters of the through holes 142a may be different among the upstream side trap member 140-1, the upstream side trap member 140-2, and the upstream side trap member 140-3. As such, the amount of the gas stream passing through the plurality of upstream side trap members, and the amount of the reaction product trapped by the plurality of upstream side trap members from the gas stream may be finely adjusted.

### Modified Example 2

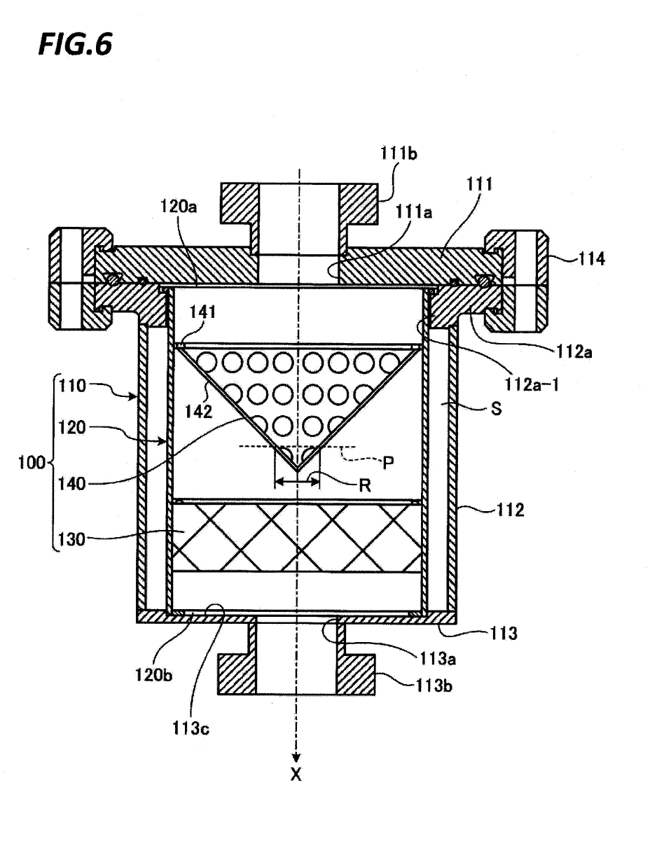

In the above-described exemplary embodiment, although an example in which the downstream side trap member 130 is disposed at a position which is not spaced apart from the downstream side end wall 113 toward the upstream side end wall 111 in the inner cylindrical member 120 has been illustrated, the present disclosure is not limited thereto. Below, the trap apparatus related to Modified Example 2 will be described. FIG. 6 is a sectional view of Modified Example 2 of the trap apparatus of the exemplary embodiment.

As illustrated in FIG. 6, in the trap apparatus according to Modified Example 2, the downstream side trap member 130 is disposed at a spaced position which is spaced apart from the downstream side end wall 113 by a predetermined distance towards the upstream side end wall 111 in the inner cylindrical member 120. Here, the predetermined distance may be 25 mm to 100 mm.

As described above, according to the trap apparatus of Modified Example 2, the downstream side trap member 130 is disposed at a position spaced apart from the downstream side end wall 113 by a predetermined distance towards the upstream side end wall 111 in the inner cylindrical member 120. Due to this, according to the trap apparatus of Modified Example 2, the reaction product included in the gas stream may be effectively removed while reducing a pressure loss in the inside of the inner cylindrical member 120.

From the foregoing descriptions, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A trap apparatus comprising:
a first cylindrical member including a space;
a second cylindrical member removably disposed in the space and including an upstream side opening which allows a gas stream to flow in therethrough, and a downstream side opening which allows the gas stream flowing in from the upstream side opening to flow out therethrough;
a downstream side trap member which is disposed inside the second cylindrical member to block the downstream side opening; and
an upstream side trap member which is disposed between the downstream side trap member and the upstream side opening of the second cylindrical member and includes a concave portion recessed in a direction approaching the downstream side trap member.

2. The trap apparatus of claim 1, wherein the upstream side trap member is formed such that a diameter of the concave portion gets smaller along the direction approaching the downstream side trap member.

3. The trap apparatus of claim 1, wherein the upstream side trap member is formed in a conical shape which gets sharper in the direction approaching the downstream side trap member.

4. The trap apparatus of claim 1, wherein a plurality of upstream side trap members is disposed between the downstream side trap member and the upstream side opening of the second cylindrical member along the direction approaching the downstream side trap member.

5. The trap apparatus of claim 4, wherein each of the plurality of upstream side trap members includes through holes which allow the gas stream to pass therethrough, and
densities and/or diameters of the through holes is different among the pluralities of upstream side trap members.

6. The trap apparatus of claims 1, wherein the first cylindrical member includes:
a cylinder body which surrounds a lateral side of the second cylindrical member;
an upstream side end wall of the cylinder body which is removably mounted on the cylinder body to block an upstream side opening side end of the second cylindrical member; and
a downstream side end wall of the cylinder body which is removably mounted on the cylinder body to block a downstream side opening side end of the second cylindrical member to form the space together with the cylinder body and the upstream side end wall, and
wherein the downstream side trap member is disposed at a position spaced apart from the downstream side end wall by a predetermined distance toward the upstream side end wall inside the second cylindrical member.

7. A substrate processing apparatus comprising:
a processing container configured to perform a plasma processing on a substrate to be processed;
an exhaust device configured to reduce a pressure within the processing container;
an exhaust flow path which connects the processing container and the exhaust device; and
a trap apparatus provided in the exhaust flow path,
wherein the trap apparatus includes:
a first cylindrical member including a space;
a second cylindrical member removably disposed in the space and including an upstream side opening which allows a gas stream to flow in therethrough, and a downstream side opening which allows the gas stream flowing in from the upstream side opening to flow out therethrough;
a downstream side trap member disposed inside the second cylindrical member to block the downstream side opening; and
an upstream side trap member disposed between the downstream side trap member and the upstream side opening of the second cylindrical member and includes a concave portion recessed in a direction approaching the downstream side trap member.
